(19) United States
(12) Patent Application Publication
(10) Pub. No.: US 2020/0218157 A1
(43) Pub. Date: Jul. 9, 2020

(54) PLASMA PROCESSING METHOD FOR PROCESSING SUBSTRATE

(71) Applicant: XIA TAI XIN SEMICONDUCTOR (QING DAO) LTD., Qingdao (CN)

(72) Inventor: SEUNG-BONG CHOI, Singapore (SG)

(21) Appl. No.: 16/711,732

(22) Filed: Dec. 12, 2019

Related U.S. Application Data
(60) Provisional application No. 62/781,627, filed on Dec. 19, 2018.

(51) Int. Cl. G03F 7/42; H01L 21/027; H01L 21/683; H01L 21/687; H01L 21/67; H01L 21/3105; H01J 37/32; B08B 5/00

(52) U.S. Cl. CPC G03F 7/427; H01L 21/0273; H01L 21/6833; H01L 21/68742; H01J 2237/335; H01L 21/31058; H01J 37/32715; B08B 5/00; H01L 21/67028

(57) ABSTRACT

A method for utilizing plasma processing for removing polymer residue during semiconductor manufacture is implemented in a plasma processing device. The plasma processing device includes a processing chamber and an electrostatic chuck therein. The electrostatic chuck includes a support surface and lift pin configured to be raised from a first position to a second position. Disposing the substrate on the supporting surface when the lift pin is at the first position. Generating a first plasma in the processing chamber, the first plasma formed from a first processing gas. The first processing gas includes a first mixing gas including hydrogen and nitrogen. Raising the lift pin to the second position to separate the substrate from the support surface. Generating a second plasma in the processing chamber, the second plasma formed from a second processing gas. The second processing gas includes a second mixing gas including hydrogen and nitrogen.

### FIELD

The subject matter herein generally relates to semiconductor manufacture, and more particularly, to a plasma processing method.

### BACKGROUND

In the manufacture of semiconductor devices, patterns of a photo mask are transferred to a photoresist on a semiconductor substrate by a photolithography process. In the photolithography process, the photoresist is formed on the semiconductor substrate, and is exposed and developed to form desired patterns. Then, the semiconductor substrate is etched so that the patterns of the photoresist are transferred to the semiconductor substrate. The etching process may be a wet etching process or a dry etching process (such as a reactive ion etching process) depending on the material of the substrate. After the semiconductor substrate is etched, the photoresist is removed because the photoresist is no longer needed as a protective layer. The removal of the photoresist is called a stripping process.

The stripping process may be performed during a wet stripping process or a dry stripping process. The wet stripping process removes the photoresist by dissolving the photoresist in an organic solvent, or by oxidizing the carbon element of the photoresist to carbon dioxide by an inorganic solvent. The dry stripping process removes the photoresist by plasma.

However, during the etching process of the semiconductor substrate, polymer residue may adhere to an edge of the semiconductor substrate, and may form particles after being detached from the edge. The polymer residue disposed on an upper region of the edge of the semiconductor substrate may be removed during a dry stripping process. However, the polymer residue disposed on a lower region of the edge of the semiconductor substrate is not easily removed, and the polymer residue which remains on the semiconductor substrate may reduce the yield of the semiconductor device.

### BRIEF DESCRIPTION OF THE DRAWINGS

Implementations of the present disclosure will now be described, by way of embodiments, with reference to the attached figures.

FIG. 1 is a flowchart of an embodiment of a plasma processing method for processing a substrate according to the present disclosure.

FIG. 2 is a schematic view of a plasma processing device used in the method of FIG. 1.

FIG. 3 is similar to FIG. 2, but showing the plasma processing device in another state.

FIG. 4 is a schematic view of the substrate processed by the plasma processing device of FIGS. 2 and 3.

FIG. 5 is a flowchart of another embodiment of a plasma processing method for processing a substrate according to the present disclosure.

FIG. 6 is a schematic view of a plasma processing device used in the method of FIG. 5.

FIG. 7 is similar to FIG. 6, but showing the plasma processing device in another state.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

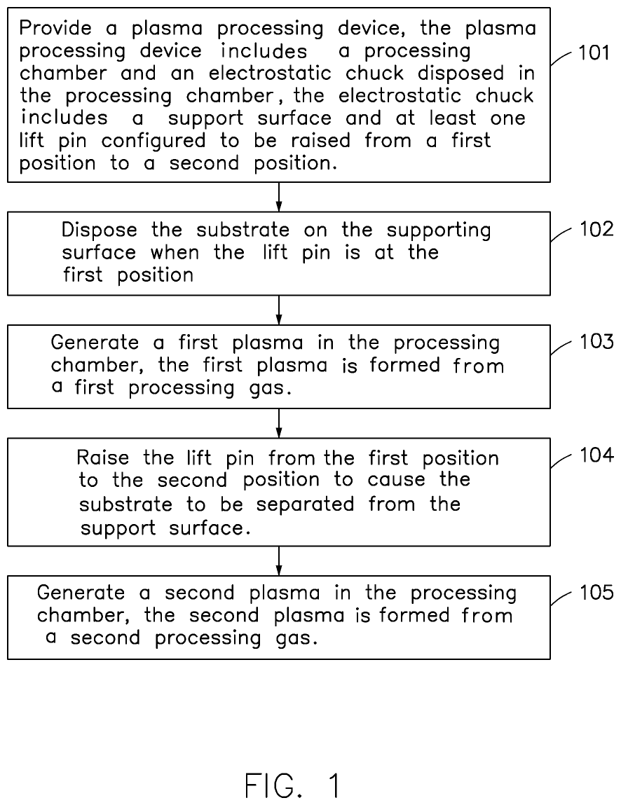

Referring to FIG. 1, a plasma processing method for processing a substrate is presented in accordance with an embodiment. The method is provided by way of example, as there are a variety of ways to carry out the method. The method may begin at block 101.

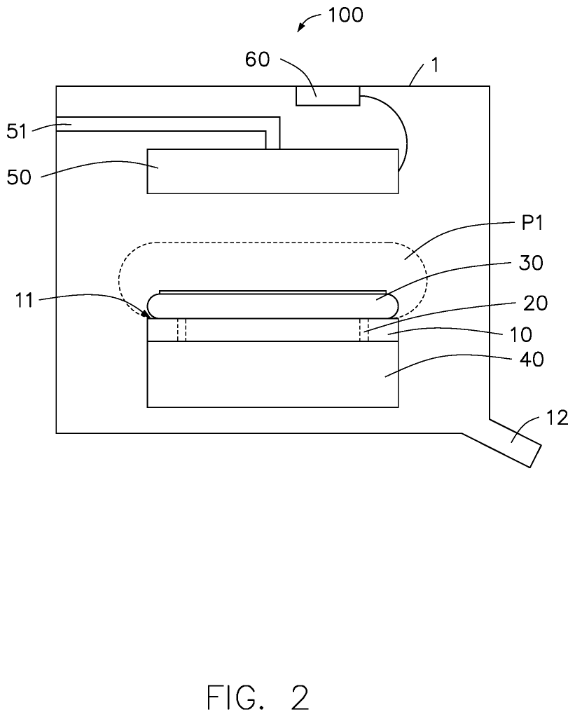

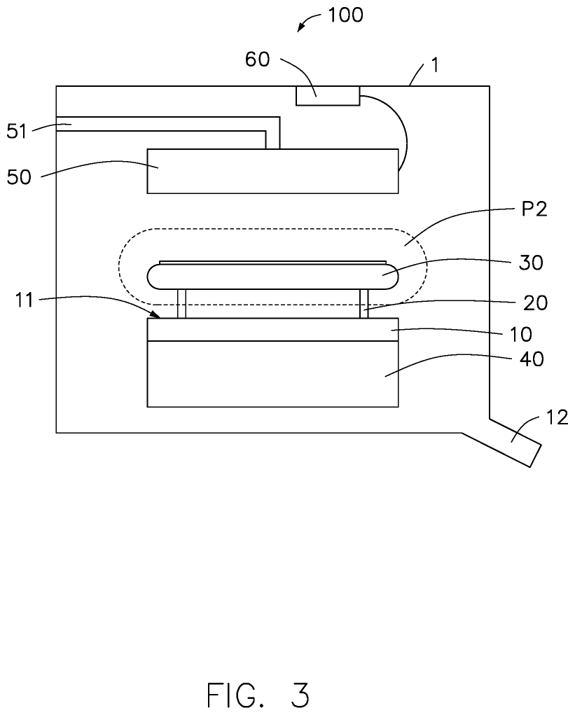

At block 101, referring to FIGS. 2 and 3, a plasma processing device 100 is provided. The plasma processing device 100 includes a processing chamber 1 and an electrostatic chuck 10 disposed in the processing chamber 1. The electrostatic chuck 10 includes a support surface 11 and at least one lift pin 20 configured to be raised from a first position (shown in FIG. 2) to a second position (shown in FIG. 3). The first position is that the lift pin 20 is not higher than the support surface 11. The second position is that the lift pin 20 is higher than the support surface 11.

In some embodiments, the electrostatic chuck 10 may further include a driver (such as a motor, not shown). The driver can lift the lift pin 20 from the first position to the second position.

At block 102, referring to FIG. 2, the substrate 30 is disposed on the supporting surface 11 when the lift pin 20 is at the first position.

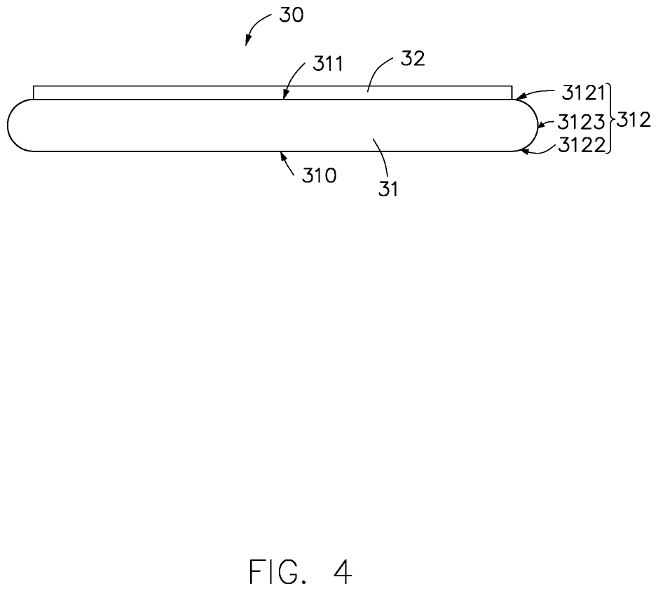

In some embodiments, the substrate 30 may be formed by etching, ion implantation, ion doping, photolithography, or thin film deposition process. Referring to FIG. 4, the substrate 30 includes a substrate body 31 and a photoresist layer 32. The substrate body 31 and the photoresist layer 32 may have same patterns. The substrate body 31 includes a lower surface 310 facing the support surface 11, an upper surface 311 opposite to the lower surface 310, and a side surface 312 connected between the lower surface 310 and the upper surface 311. The photoresist layer 32 is formed on the upper surface 311. The side surface 312 includes a first bevel region 3121 adjacent to the upper surface 311, a second bevel region 3122 adjacent to the lower surface 310, and a central region 3123 between the first bevel region 3121 and the second bevel region 3122. The first bevel region 3121 and the second bevel region 3122 are inclined with respect to the upper surface 311 and the lower surface 310, respectively. In some embodiments, the substrate body 31 may be a semiconductor wafer, a quartz substrate, or a glass substrate.

During the etching process of the substrate body 31, polymer residue from the photoresist layer 32 may be generated and adhere to the surface of the substrate body 31 exposed from the photoresist layer 32. For example, the polymer residue from the photoresist layer 32 may adhere to the first bevel region 3121 and the central region 3123. Furthermore, since the second bevel region 3122 is inclined with respect to the lower surface 310, the second bevel region 3122 is also exposed during the etching process. Thus, the polymer residue may also adhere to the second bevel region 3122.

At block 103, a first plasma P1 is generated in the processing chamber 1. The first plasma P1 is formed from a first processing gas. The first processing gas includes a first mixing gas, and the first mixing gas includes hydrogen and nitrogen.

The first plasma P1 may remove the photoresist layer 32, and may also remove the polymer residue disposed on the first bevel region 3121 and the central region 3123. Since the first mixing gas includes hydrogen and nitrogen, the first plasma P1 includes hydrogen ions and nitrogen ions. The hydrogen ions will remove oxygen atoms and other atoms of the polymer residue on the substrate body 31. The nitrogen ions will reduce the number of the free-end bonds of the polymer residue so as to reduce their adherence to the substrate body 31. Therefore, the first plasma P1 may remove the photoresist layer 32 and the polymer residue. Furthermore, the first plasma P1 may decrease a contact resistance of the substrate body 31 during the etching process (for example, when the substrate body 31 includes silicon, the first plasma P1 may decrease the amount of silicon dioxide generated during the etching process).

In some embodiments, the hydrogen of the first mixing gas has a volume percentage of 1% to 10% in the first mixing gas, and the nitrogen of the first mixing gas has a volume percentage of 90% to 99% in the first mixing gas. In some embodiments, the hydrogen of the first mixing gas has a volume percentage of 4% in the first mixing gas, and the nitrogen of the first mixing gas has a volume percentage of 96% in the first mixing gas, which allows the first plasma P1 to remove the photoresist layer 32 and the polymer residue more effectively.

In some embodiments, in order to increase an etching rate of the photoresist layer 32 and the polymer residue, the first processing gas further comprises oxygen, which causes the first plasma P1 to have oxygen ions. The amount of the oxygen in the first processing gas may be set to cause the first plasma P1 to have an improved etching rate and to reduce the contact resistance to a certain range.

In some embodiments, the plasma processing device 100 further comprises an upper electrode 50, a lower electrode 40, and a high frequency source 60. The upper electrode 50 and the lower electrode 40 are disposed in the processing chamber 1 and face each other. The electrostatic chuck 10 is disposed above the lower electrode 40 and between the upper electrode 50 and the lower electrode 40. In some embodiments, the plasma processing device 100 further includes a gas channel 51 connected to the upper electrode 50. The first processing gas is supplied to the upper electrode 50 through the gas channel 51. The upper electrode 50 may serve as a shower head spraying the first processing gas to a region between the upper electrode 50 and the lower electrode 40. The high frequency source 60 supplies high frequency power to the upper electrode 50 or the lower electrode 40, thereby ionizing the first processing gas to form the first plasma P1.

In some embodiments, the processing chamber 1 may further include an outlet 12 near the bottom of the processing chamber 1. The by-products generated during the etching process may be exhausted from the processing chamber 1 through the outlet 12.

In some embodiments, the electrostatic chuck 10 further includes a bias electrode (not shown). When radio frequency (RF) power is provided to the bias electrode, a bias voltage is generated in the electrostatic chuck 10, which drives the first plasma P1 to move towards the electrostatic chuck 10. The photoresist layer 32 and the polymer residue are then etched by the first plasma P1.

In some embodiments, the electrostatic chuck 10 further includes an electrostatic electrode (not shown). When a DC voltage is applied to the electrostatic electrode, opposite charges are generated at the electrostatic chuck 10 and the substrate 30. Accordingly, the substrate 30 is attracted to and held on the electrostatic chuck 10 under an electrostatic force, thereby preventing the substrate 30 from moving during the etching process.

At block 104, referring to FIG. 3, the lift pin 20 is raised from the first position to the second position to cause the substrate 30 to be separated from the support surface 11.

By separating the substrate 30 from the support surface 11, a distance between the second bevel region 3122 and the support surface 11 is increased. Thus, the polymer residue disposed on the second bevel region 3122 may then be easily removed by plasma.

At block 105, a second plasma P2 is generated in the processing chamber 1. The second plasma P2 is formed from a second processing gas. The second processing gas includes a second mixing gas, and the second mixing gas includes hydrogen and nitrogen.

The second plasma P2 removes the polymer residue disposed on the second bevel region 3122. In some embodiments, when the polymer residue remains on the first bevel region 3121 and the central region 3123, the second plasma P2 further removes the polymer residue disposed on the first bevel region 3121 and the central region 3123. Since the second processing gas also includes hydrogen and nitrogen, the second plasma P2 also reduces the contact resistance of the substrate body 31 during the etching process.

In some embodiments, the hydrogen of the second mixing gas has a volume percentage of 1% to 10% in the second mixing gas, and the nitrogen of the second mixing gas has a volume percentage of 90% to 99% in the second mixing gas. In some embodiments, the hydrogen of the second mixing gas has a volume percentage of 4% in the second mixing gas, and the nitrogen of the second mixing gas has a volume percentage of 96% in the second mixing gas, which allows the second plasma P2 to remove the photoresist layer 32 and the polymer residue more effectively.

In some embodiments, in order to increase the etching rate of the photoresist layer 32 and the polymer residue, the second processing gas further comprises oxygen, which causes the second plasma P2 to have oxygen ions.

In some embodiments, the first processing gas and the second processing gas may be the same. That is, the first plasma P1 and the second plasma P2 may have same components and same amount of each component. Furthermore, the plasma processing device 100 may have a single gas source (not shown). Both of the first processing gas and the second processing gas are supplied to the gas channel 51 from the gas source, which reduces cost.

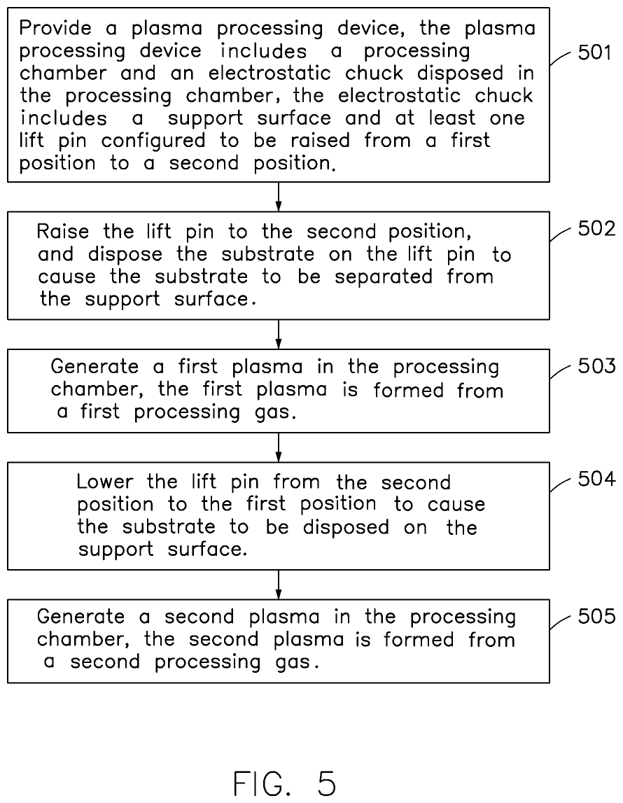

Referring to FIG. 5, a plasma processing method for processing a substrate is presented in accordance with another embodiment. The method is provided by way of example, as there are a variety of ways to carry out the method. The method may begin at block 501.

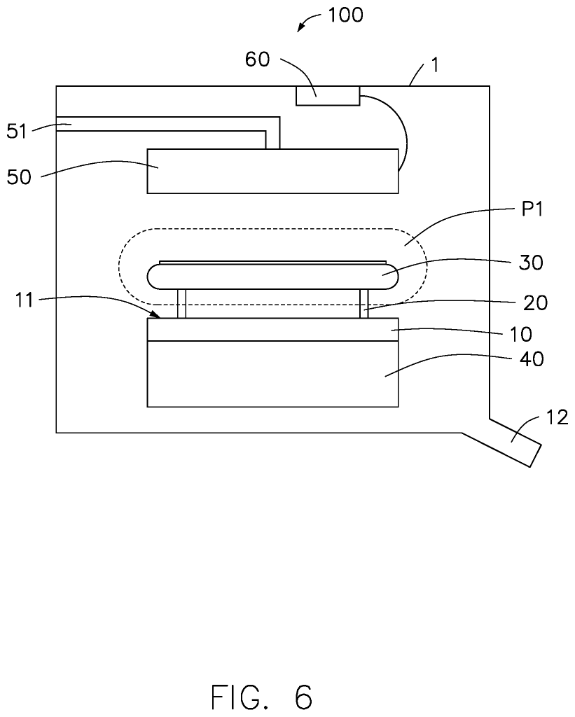

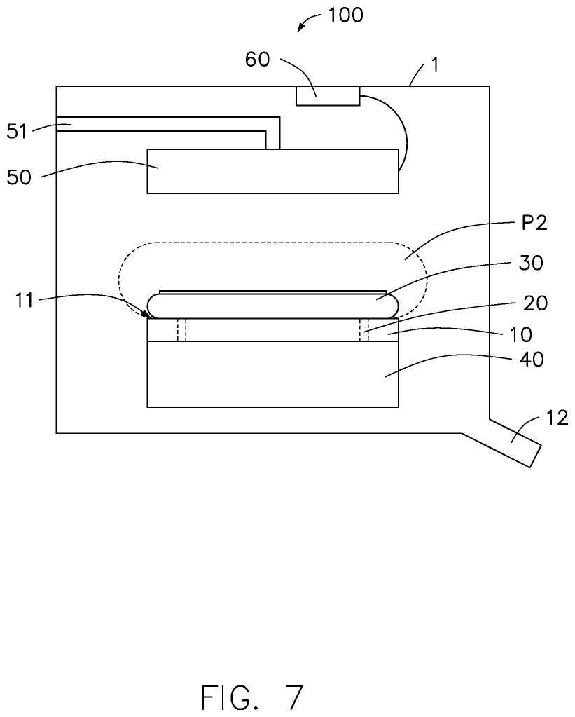

At block 501, referring to FIGS. 6 and 7, a plasma processing device 100 is provided. The plasma processing device 100 includes a processing chamber 1 and an electrostatic chuck 10 disposed in the processing chamber 1. The electrostatic chuck 10 includes a support surface 11 and at least one lift pin 20 configured to be raised from a first position (shown in FIG. 7) to a second position (shown in FIG. 6). The first position is that the lift pin 20 is not higher than the support surface 11. The second position is that the lift pin 20 is higher than the support surface 11.

At block 502, referring to FIG. 6, the lift pin 20 is raised to the second position, and the substrate 30 is disposed on the lift pin 20 to cause the substrate 30 to be separated from the support surface 11.

By separating the substrate 30 from the support surface 11, the distance between the second bevel region 3122 and the support surface 11 is increased. Then the polymer residue disposed on the second bevel region 3122 may be removed by plasma.

At block 503, a first plasma P1 is generated in the processing chamber 1. The first plasma P1 is formed from a first processing gas. The first processing gas includes a first mixing gas, and the first mixing gas includes hydrogen and nitrogen.

The first plasma P1 removes the polymer residue disposed on the second bevel region 3122. In some embodiments, when the polymer residue is also disposed on the first bevel region 3121, the first plasma P1 also removes the polymer residue disposed on the first bevel region 3121. In some embodiments, the first plasma P1 also removes the photoresist layer 32.

In some embodiments, the hydrogen of the first mixing gas has a volume percentage of 1% to 10% in the first mixing gas, and the nitrogen of the first mixing gas has a volume percentage of 90% to 99% in the first mixing gas. In some embodiments, the hydrogen of the first mixing gas has a volume percentage of 4% in the first mixing gas, and the nitrogen of the first mixing gas has a volume percentage of 96% in the first mixing gas.

In some embodiments, in order to increase the etching rate of the photoresist layer 32 and the polymer residue, the first processing gas further comprises oxygen, which causes the first plasma P1 to have oxygen ions.

In some embodiments, the plasma processing method may also include following blocks.

At block 504, referring to FIG. 7, the lift pin 20 is lowered from the second position to the first position to cause the substrate 30 to be disposed on the support surface 11.

At block 505, a second plasma P2 is generated in the processing chamber 1. The second plasma P2 is formed from a second processing gas. The second processing gas includes a second mixing gas, and the second mixing gas includes hydrogen and nitrogen.

The second plasma P2 may remove the photoresist layer 32, and also remove the polymer residue disposed on the first bevel region 3121 and the central region 3123. In some embodiments, when the photoresist layer 32 remains on the substrate body 31 or the polymer residue remains on the first bevel region 3121 and the central region 3123, the second plasma P2 removes the photoresist layer 32, and/or removes the polymer residue disposed on the first bevel region 3121 and the central region 3123.

In some embodiments, the hydrogen of the second mixing gas has a volume percentage of 1% to 10% in the second mixing gas, and the nitrogen of the second mixing gas has a volume percentage of 90% to 99% in the second mixing gas. In some embodiments, the hydrogen of the second mixing gas has a volume percentage of 4% in the second mixing gas, and the nitrogen of the second mixing gas has a volume percentage of 96% in the second mixing gas.

In some embodiments, in order to increase the etching rate of the photoresist layer 32 and the polymer residue, the second processing gas further comprises oxygen, which causes the second plasma P2 to have oxygen ions.

In some embodiments, the first processing gas and the second processing gas may be the same. That is, the first plasma P1 and the second plasma P2 may have same components and same amount of each component.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A plasma processing method for processing a substrate, comprising:
providing a plasma processing device, the plasma processing device comprising a processing chamber and an electrostatic chuck disposed in the processing chamber, the electrostatic chuck comprising a support surface and at least one lift pin configured to be raised from a first position to a second position, wherein the first position is that the at least one lift pin is not higher than the support surface, the second position is that the at least one lift pin is higher than the support surface;
disposing the substrate on the supporting surface when the at least one lift pin is at the first position;
generating a first plasma in the processing chamber, the first plasma formed from a first processing gas, the first processing gas comprising a first mixing gas including hydrogen and nitrogen;
raising the at least one lift pin from the first position to the second position to cause the substrate to be separated from the support surface; and
generating a second plasma in the processing chamber, the second plasma formed from a second processing gas, the second processing gas comprising a second mixing gas including hydrogen and nitrogen.

2. The plasma processing method of claim 1, wherein the hydrogen of the first mixing gas has a volume percentage of 1% to 10% in the first mixing gas, and the nitrogen of the first mixing gas has a volume percentage of 90% to 99% in the first mixing gas.

3. The plasma processing method of claim 1, wherein the hydrogen of the first mixing gas has a volume percentage of 4% in the first mixing gas, and the nitrogen of the first mixing gas has a volume percentage of 96% in the first mixing gas.

4. The plasma processing method of claim 1, wherein the first processing gas further comprises oxygen.

5. The plasma processing method of claim 1, wherein the hydrogen of the second mixing gas has a volume percentage of 1% to 10% in the second mixing gas, and the nitrogen of the second mixing gas has a volume percentage of 90% to 99% in the second mixing gas.

6. The plasma processing method of claim 1, wherein the hydrogen of the second mixing gas has a volume percentage of 4% in the second mixing gas, and the nitrogen of the second mixing gas has a volume percentage of 96% in the second mixing gas.

7. The plasma processing method of claim 1, wherein the second processing gas further comprises oxygen.

8. The plasma processing method of claim 1, wherein the plasma processing device further comprises an upper electrode, a lower electrode, and a high frequency source, the upper electrode and the lower electrode are disposed in the processing chamber and face each other, the electrostatic chuck is disposed above the lower electrode and between the upper electrode and the lower electrode;
the high frequency source is configured to supply high frequency power to the upper electrode or the lower electrode, thereby ionizing the first processing gas and the second processing gas to the first plasma and the second plasma, respectively.

9. The plasma processing method of claim 8, wherein the plasma processing device further comprises a gas channel connected to the upper electrode, the first processing gas and the second processing gas are supplied to the upper electrode through the gas channel, and the upper electrode sprays the first processing gas and the second processing gas to a region between the upper electrode and the lower electrode.

10. The plasma processing method of claim 9, wherein the plasma processing device further comprises a gas source connected to the gas channel, both of the first processing gas and the second processing gas are supplied to the gas channel from the gas source.

11. A plasma processing method for processing a substrate, comprising:
providing a plasma processing device, the plasma processing device comprising a processing chamber and an electrostatic chuck disposed in the processing chamber, the electrostatic chuck comprising a support surface and at least one lift pin configured to be raised from a first position to a second position, wherein the first position is that the at least one lift pin is not higher than the support surface, the second position is that the at least one lift pin is higher than the support surface;
raising the at least one lift pin to the second position, and disposing the substrate on the at least one lift pin to cause the substrate to be separated from the support surface; and
generating a first plasma in the processing chamber, the first plasma formed from a first processing gas, the first processing gas comprising a first mixing gas including hydrogen and nitrogen.

12. The plasma processing method of claim 11, further comprising:
lowering the at least one lift pin from the second position to the first position to cause the substrate to be disposed on the support surface; and
generating a second plasma in the processing chamber, the second plasma formed from a second processing gas, the second processing gas comprising a second mixing gas including hydrogen and nitrogen.

13. The plasma processing method of claim 12, wherein the hydrogen of the second mixing gas has a volume percentage of 1% to 10% in the second mixing gas, and the nitrogen of the second mixing gas has a volume percentage of 90% to 99% in the second mixing gas.

14. The plasma processing method of claim 12, wherein the hydrogen of the second mixing gas has a volume percentage of 4% in the second mixing gas, and the nitrogen of the second mixing gas has a volume percentage of 96% in the second mixing gas.

15. The plasma processing method of claim 12, wherein the second processing gas further comprises oxygen.

16. The plasma processing method of claim 11, wherein the hydrogen of the first mixing gas has a volume percentage of 1% to 10% in the first mixing gas, and the nitrogen of the first mixing gas has a volume percentage of 90% to 99% in the first mixing gas.

17. The plasma processing method of claim 11, wherein the hydrogen of the first mixing gas has a volume percentage of 4% in the first mixing gas, and the nitrogen of the first mixing gas has a volume percentage of 96% in the first mixing gas.

18. The plasma processing method of claim 11, wherein the first processing gas further comprises oxygen.

19. The plasma processing method of claim 12, wherein the plasma processing device further comprises an upper electrode, a lower electrode, and a high frequency source, the upper electrode and the lower electrode are disposed in the processing chamber and face each other, the electrostatic chuck is disposed above the lower electrode and between the upper electrode and the lower electrode;
the high frequency source is configured to supply high frequency power to the upper electrode or the lower electrode, thereby ionizing the first processing gas and the second processing gas to the first plasma and the second plasma, respectively.

20. The plasma processing method of claim 19, wherein the plasma processing device further comprises a gas channel connected to the upper electrode, the first processing gas and the second processing gas are supplied to the upper electrode through the gas channel, and the upper electrode sprays the first processing gas and the second processing gas to a region between the upper electrode and the lower electrode.
